(19) United States
(12) Patent Application Publication
(10) Pub. No.: US 2006/0157697 A1
(43) Pub. Date: Jul. 20, 2006

(54) System and method for adjusting a manufacturing condition of an electronic device and method for manufacturing an electronic device

(76) Inventor: Hajime Nagano, Yokkaichi-shi (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 11/232,851

(22) Filed: Sep. 23, 2005

(30) Foreign Application Priority Data
Sep. 29, 2004 (JP) P2004-285528

(51) Int. Cl. H01L 21/66; H01L 23/58; G01R 31/26

(52) U.S. Cl. 257/48; 438/14

(57) ABSTRACT

A system for adjusting a manufacturing condition of an electronic device includes: an inspection tool configured to inspect a plurality of protrusions on a substance layer for manufacturing an electronic device; a height calculation unit configured to calculate each of heights of the protrusions, based on the inspection result; and an adjustment unit configured to adjust a manufacturing condition of the electronic device in order to remove the protrusions, based on the heights.

### CROSS REFERENCE TO RELATED APPLICATIONS AND INCOORPORATED BY REFERRENCE

The application is based on and claims the benefit of priority from the prior Japanese Patent Applications No. P2004-285528, filed on Sep. 29, 2004; the entire contents of which are incorporated herein by reference.

### BACKGROUND OF THE INVENTION

1. Field of the Invention

The present invention relates to technology for manufacturing an electronic device, more particularly, to a system for adjusting a manufacturing condition, a method for adjusting a manufacturing condition and a method for manufacturing an electronic device.

2. Description of the Related Art

In a manufacturing process for a semiconductor device as an example, of an electronic device, a semiconductor layer of poly crystalline silicon or amorphous silicon, which will later be delineated to define gate electrodes, is formed on a semiconductor substrate through a gate insulating layer. In an etching process, a film thickness of the semiconductor layer is inspected and then the semiconductor layer is processed under an etching condition according to the film-thickness inspection result.

When stacking a semiconductor layer, a minute foreign substance may be mixed or generated in the semiconductor layer, which may result in generation of a minute protrusion (hereinafter, simply referred to as a “protrusion”) on the semiconductor layer. The protrusion is an area in the semiconductor layer where the film thickness is locally thicker than the rest of areas of the semiconductor layer.

In earlier technology, when a film thickness of a semiconductor layer was inspected, the film thickness of such a protrusion was not inspected. Therefore, after removal of a semiconductor layer in an etching process, a residue of the semiconductor layer remained in the areas where the protrusion was present. As a result, a processing defect such as a short circuit between gate electrodes and failures in element isolation regions are generated, causing a decrease in the yield of semiconductor devices.

### SUMMARY OF THE INVENTION

An aspect of the present invention inheres in a system for adjusting a manufacturing condition of an electronic device including: an inspection tool configured to inspect a plurality of protrusions on a substance layer for manufacturing an electronic device; a height calculation unit configured to calculate each of heights of the protrusions, based on the inspection result; and an adjustment unit configured to adjust a manufacturing condition of the electronic device in order to remove the protrusions, based on the heights.

Another aspect of the present invention inheres in a method for adjusting a manufacturing condition of an electronic device including: inspecting a plurality of protrusions on a substance layer for manufacturing an electronic device; calculating each of heights of the protrusions, based on the inspection result; and adjusting a manufacturing condition of the electronic device, in order to remove the protrusions, based on the heights.

An additional aspect of the present invention inheres in a method for manufacturing an electronic device including: depositing a substance layer on a substrate; inspecting a plurality of protrusions on the substance layer; calculating each of heights of the protrusions, based on the inspection result; adjusting a condition for processing the substance layer, based on the heights; and processing the substance layer so as to manufacture the electronic device, by using the adjusted condition in order to remove the protrusions.

### BRIEF DESCRIPTION OF DRAWINGS

FIG. 1 is a block diagram showing an example of a system for adjusting a manufacturing condition according to an embodiment of the present invention.

FIG. 2 is a cross-sectional view for explaining an example of a method for manufacturing an electronic device according to the embodiment of the present invention.

FIG. 3 is an oblique view of a surface of a semiconductor layer for explaining inspection of a protrusion according to the embodiment of the present invention protrusion.

FIG. 4 is a graph showing correlation between etching time and etching amount of an etching tool according to the embodiment of the present invention.

FIG. 5 is a schematic view for explaining an example of a method for calculating a height of the protrusion according to the embodiment of the present invention.

FIG. 6 is a flow chart for explaining an example of a method for adjusting a manufacturing condition according to the embodiment of the present invention.

FIG. 7 is a graph showing correlation between etching amount and acceleration voltage of etching ion according to the embodiment of the present invention.

FIG. 8 is a plan view of a semiconductor device provided by a method for manufacturing a semiconductor device according to the embodiment of the present invention.

FIG. 9A is a sectional process view in IXA-IXA direction of FIG. 8 for explaining an example of a method for manufacturing an electronic device according to the embodiment of the present invention after the process of FIG. 2.

FIG. 9B is a sectional process view in IXB-IXB direction of FIG. 8 for explaining the example of the method for manufacturing an electronic device according to the embodiment of the present invention.

FIG. 10A is a sectional process view in the IXA-IXA direction of FIG. 8 for explaining the example of the method for manufacturing an electronic device according to the embodiment of the present invention after the process of FIG. 9A.

FIG. 10B is a sectional process view in the IXB-IXB direction of FIG. 8 for explaining the example of the method for manufacturing an electronic device according to the embodiment of the present invention after the process of FIG. 9B.

FIG. 11A is a sectional process view in the IXA-IXA direction of FIG. 8 for explaining the example of the method for manufacturing an electronic device according to the embodiment of the present invention after the process of FIG. 10A.

FIG. 11B is a sectional process view in the IXB-IXB direction of FIG. 8 for explaining the example of the method for manufacturing an electronic device according to the embodiment of the present invention after the process of FIG. 10B.

FIG. 12A is a sectional process view in the IXA-IXA direction of FIG. 8 for explaining the example of the method for manufacturing an electronic device according to the embodiment of the present invention after the process of FIG. 11A.

FIG. 12B is a sectional process view in the IXB-IXB direction of FIG. 8 for explaining the example of the method for manufacturing an electronic device according to the embodiment of the present invention after the process of FIG. 11B.

FIG. 13A is a sectional process view in the IXA-IXA direction of FIG. 8 for explaining the example of the method for manufacturing an electronic device according to the embodiment of the present invention after the process of FIG. 12A.

FIG. 13B is a sectional process view in the IXB-IXB direction of FIG. 8 for explaining the example of the method for manufacturing an electronic device according to the embodiment of the present invention after the process of FIG. 12B.

FIG. 14A is a sectional process view in the IXA-IXA direction of FIG. 8 for explaining the example of the method for manufacturing an electronic device according to the embodiment of the present invention after the process of FIG. 13A.

FIG. 14B is a sectional process view in the IXB-IXB direction of FIG. 8 for explaining the example of the method for manufacturing an electronic device according to the embodiment of the present invention after the process of FIG. 13B.

FIG. 15A is a sectional process view in the IXA-IXA direction of FIG. 8 for explaining the example of the method for manufacturing an electronic device according to the embodiment of the present invention after the process of FIG. 14A.

FIG. 15B is a sectional process view in the IXB-IXB direction of FIG. 8 for explaining the example of the method for manufacturing an electronic device according to the embodiment of the present invention after the process of FIG. 14B.

FIG. 16 is a block diagram showing an example of a system for adjusting a manufacturing condition according to a first modification of the embodiment of the present invention.

FIG. 17 is a plan view of a semiconductor layer according to the first modification of the embodiment of the present invention.

FIG. 18 is a graph showing the relationship between a diameter of a protrusion and processing defect rate when a gate electrode interval is changed according to the first modification of the embodiment of the present invention.

FIG. 19 is a flow chart for explaining an example of a method for adjusting a manufacturing condition according to the first modification of the embodiment of the present invention.

FIG. 20 is a block diagram showing an example of a system for adjusting a manufacturing condition according to a second modification of the embodiment of the present invention.

FIG. 21 is a graph showing the correlation between deposition time of a semiconductor layer and a number of protrusions formed on a semiconductor layer according to the second modification of the embodiment of the present invention.

FIG. 22 is a flow chart for explaining an example of a method for adjusting a manufacturing condition according to the second modification of the embodiment of the present invention.

FIG. 23 is a block diagram showing an example of a system for adjusting a manufacturing condition according to a third modification of the embodiment of the present invention.

FIG. 24 is a flow chart for explaining an example of a method for adjusting a manufacturing condition according to the third modification of the embodiment of the present invention.

### DETAILED DESCRIPTION OF THE INVENTION

An embodiment and various modifications of the present invention will be described with reference to the accompanying drawings. It is to be noted that the same or similar reference numerals are applied to the same or similar parts and elements throughout the drawings, and the description of the same or similar parts and elements will be omitted or simplified.

Generally and as it is conventional in the representation of semiconductor devices, it will be appreciated that the various drawings are not drawn to scale from one figure to another nor inside a given figure, and in particular that the layer thicknesses are arbitrarily drawn for facilitating the reading of the drawings.

In the following descriptions, numerous specific details are set fourth such as specific signal values, etc. to provide a thorough understanding of the present invention. However, it will be obvious to those skilled in the art that the present invention may be practiced without such specific details. In other instances, well-known circuits have been shown in block diagram form in order not to obscure the present invention in unnecessary detail.

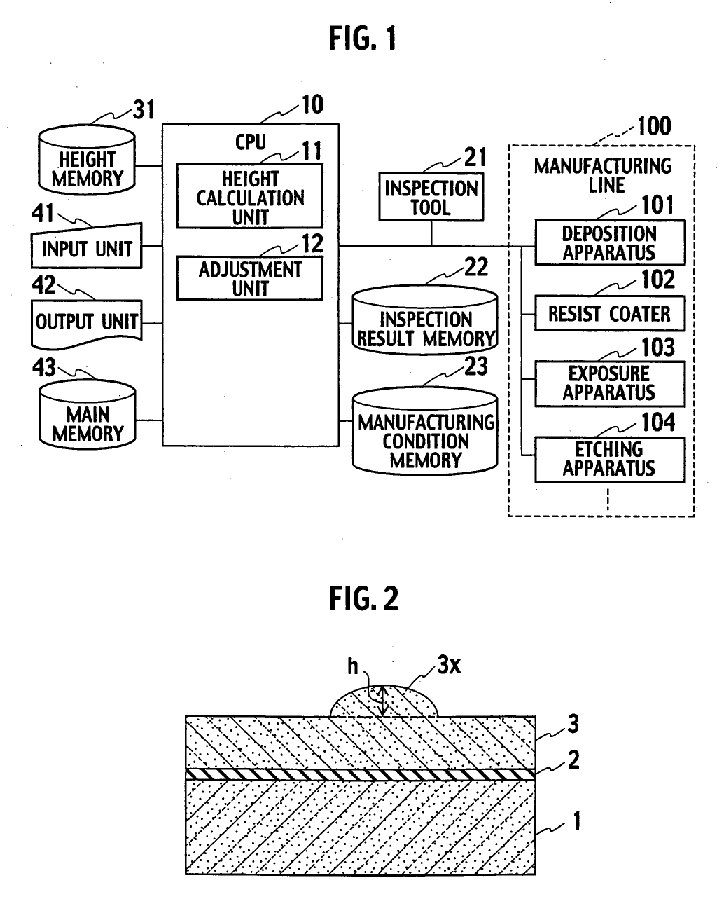

As shown in FIG. 1, a system for adjusting a manufacturing condition according to an embodiment of the present invention includes an inspection tool 21 for inspecting protrusions on a substance layer (a semiconductor layer), a height calculation unit 11 for calculating each of the heights of the protrusions, based on the inspection result, and an adjustment unit 12 for adjusting a manufacturing condition so that the protrusions is removed, based on the heights of the protrusions.

The height calculation unit 11 and the adjustment unit 12 are included in a central processing unit (CPU) 10. An inspection result memory 22, a manufacturing condition memory 23, a height memory 31, an input unit 41, an output unit 42 and a main memory 43 are connected to the CPU 10. The inspection tool 21 and a manufacturing line 100 are also connected to the CPU 10 through a communication network or the like.

The manufacturing line 100 includes a group of manufacturing apparatuses for manufacturing a semiconductor device. The group of manufacturing apparatuses includes an oxidizing apparatus such as an oxidizing reactor, a deposition apparatus 101 such as a chemical vapor deposition (CVD) apparatus, a resist coater 102 such as a spin coater, an exposure apparatus 103 such as a stepper, and an etching apparatus 104 such as a reactive ion etching (RIE) apparatus. Although not illustrated, the manufacturing line 100 also includes many other manufacturing apparatuses such as a resist remover, a dryer, a cleaning apparatus, an ion implantation apparatus and a heat treatment apparatus.

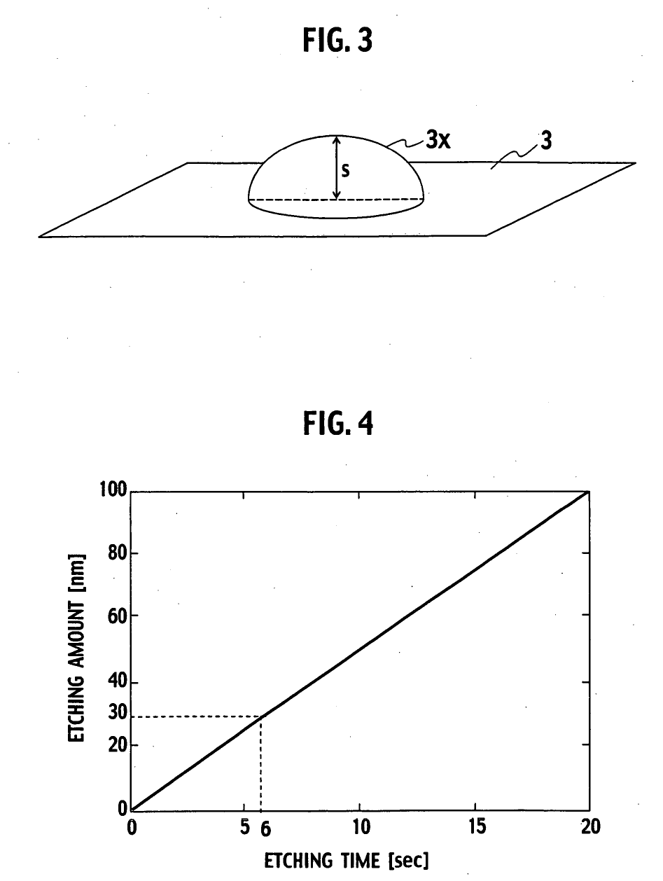

A scanning electron microscope (SEM), a laser microscope, and an atomic force microscope (AFM) can be used as the inspection tool 21. For example, the SEM sweeps an electron beam over a semiconductor wafer, except for its edge cut area, with a width of about 3 to 7 mm from the circumference, and detects secondary electrons and reflection electrons reflected from the semiconductor wafer. The inspection tool 21 inspects protrusions 3x like the one shown in FIG. 2 on the substance layer (the semiconductor layer). The semiconductor layer 3 is, for example, a gate electrode layer placed on a substrate (a semiconductor substrate) 1 through a gate insulating film 2. A number of protrusions 3x are generated on the semiconductor layer 3 due to minute foreign substances mixed or generated therein. By using the inspection tool 21, a SEM image of a surface of the semiconductor wafer viewed from an oblique direction, as shown in FIG. 3, is obtained.

The inspection result memory 23 shown in FIG. 1 stores an inspection result, such as a SEM image, obtained by the inspection tool 21. The manufacturing condition memory 23 stores conditions (manufacturing conditions), such as a deposition condition and an etching condition of the semiconductor layer in the manufacturing process for manufacturing a semiconductor device. The etching condition includes a correlation between etching time and an etching amount of the semiconductor layer as shown in FIG. 4.

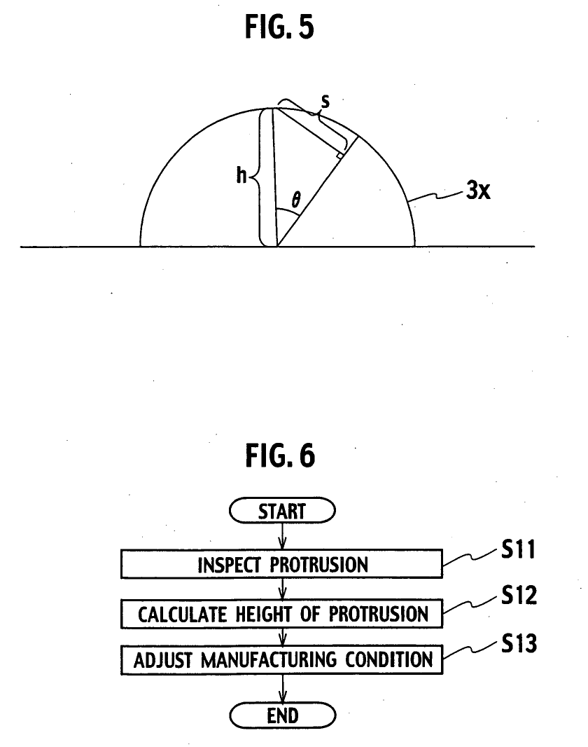

The height calculation unit 11 in the CPU 10 shown in FIG. 1 extracts, for example, about 5 to 20 relatively large protrusions, as samples, from the plurality of protrusions on the semiconductor layer 3, based on the SEM image of the semiconductor layer viewed from an oblique direction. The “relatively large” protrusions may be selected by heights of the protrusions viewed from the oblique direction or directed maximum diameters of the protrusions. The height calculation unit 11 calculates heights of the respective extracted protrusions. In the case where relatively large protrusions are extracted based on the SEM image viewed from the oblique direction, the height calculation unit 11 calculates a maximum dimension “h” (=s/sin θ) in the film-thickness direction as the height of each protrusion, as shown in FIG. 5. Here, “s” represents a maximum dimension perpendicular to a direction of a maximum diameter of the protrusion 3x measured along an oblique direction, and “θ” represents an angle of the oblique direction relative to the film-thickness direction.

The adjustment unit 12 shown in FIG. 1 adjusts the manufacturing conditions, such as an etching condition, based on the maximum dimensions of the heights “h” of the plurality of protrusions calculated by the height calculation unit 11. The protrusions with the maximum heights are removed. For example, if the height “h” of a protrusion is 30 nm, the adjustment unit 12 refers to the correlation between etching time and the etching amount, shown in FIG. 4, stored in the manufacturing condition memory 23 and extends the pre-set etching time by 6 s. The adjusted manufacturing condition is stored in the manufacturing condition memory 23, shown in FIG. 1.

The CPU 10 further includes a memory manager (not shown). The memory manager controls the inspection result memory 22, the manufacturing condition memory 23, the height memory 31, and the main memory 43 for reading and writing in information. The height memory 31 stores the height “h” of the protrusions calculated by the height calculation unit 11.

The input unit 41 may be, for example, a keyboard, a mouse, a recognition device such as an optical character readers (OCR), a drawing input device such as an image scanner, or a special input unit such as a voice input device. The output unit 42 may be a display device such as a liquid crystal display (LCD), CRT display, or a printing device such as an ink jet printer or a laser printer.

The main memory 43 includes read-only memory (ROM) and random-access memory (RAM). The ROM stores a program executed by the CPU 10 (the details of the program are described later). The RAM serves as a temporary data memory for storing data used in executing a program by the CPU 10, and used as a working domain. As the main memory 43, a flexible disk, a CD-ROM, a MO disk, etc. can be used. The system shown in FIG. 1 further has an input/output manager (interface) (not shown) connecting the input unit 41, the output unit 42 and so on to the CPU 10.

Next, an example of a method for adjusting a manufacturing condition according to the embodiment of the present invention, using by the system shown in FIG. 1, will be described, with reference to FIG. 6.

In step S11, as shown in FIG. 2, a semiconductor substrate 1, on which a semiconductor layer 3 is formed, is prepared. The inspection tool 21 shown in FIG. 1 inspects a plurality of protrusions 3x on the semiconductor layer 3. A result of the inspection by the inspection tool 21 is stored in the inspection result memory 22.

In step S12, the height calculation unit 11 reads the inspection result from the inspection result memory 22. The height calculation unit 11 then extracts about 5 to 20 protrusions, which are relatively large, from among the plurality of protrusions on the semiconductor layer 3. The height calculation unit 11 then calculates a height “h” of the protrusions for each of the extracted protrusions. The height “h” of each of the protrusions is stored in the height memory 31.

In step S13, the adjustment unit 12 reads the heights “h” of the protrusions from the height memory 31. The adjustment unit 12 then adjusts manufacturing conditions, such as etching time and the like in order to remove the protrusion 3x from the semiconductor layer 3. The adjusted manufacturing conditions are stored in the manufacturing condition memory 23.

According to the embodiment of the present invention, the protrusion 3x on the semiconductor layer 3 can be removed by etching under an adjusted etching condition stored in the manufacturing condition memory 23. Therefore, a processing defect caused by the protrusion 3x can be reduced, thus improving the yield of semiconductor devices.

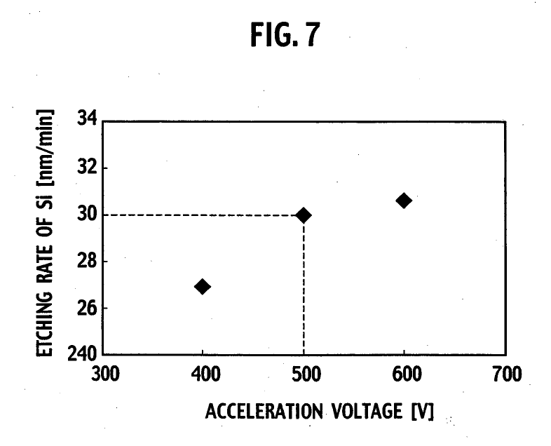

Note that the manufacturing condition memory 23 shown in FIG. 1 may store a correlation between an acceleration voltage of etching ions and an etching rate as shown in FIG. 7 as an etching condition. Instead of extending etching time, the adjustment unit 12 may increase an acceleration voltage of etching ions such that protrusions are removed based on the correlation between the acceleration voltage of etching ions and an etching rate stored in the manufacturing condition memory 23. By using an acceleration voltage of etching ions adjusted by the adjustment unit 12 in the etching process, the protrusion 3x on the semiconductor layer 3 can be removed within a fixed etching time.

The procedures shown in FIG. 6 can be executed by controlling the CPU 10 with a program, the algorisms thereof defining the procedures. The program can be stored in a computer-readable storage medium. The procedures of the method of generating mask data can be performed by reading the program from the computer-readable storage medium to the main memory 43 or the like.

Here, the “computer-readable storage medium” means any media that can store a program, including, e.g., external memory units, semiconductor memories, magnetic disks, optical disks, magneto-optical disks, magnetic tape, and the like for a computer. To be more specific, the “computer-readable storage media” include flexible disks, CD-ROMs, MO disks, and the like. For example, the main body of the system can be configured to incorporate a flexible disk drive and an optical disk drive, or to be externally connected thereto. A flexible disk is inserted into the flexible disk drive, a CD-ROM is inserted into the optical disk drive, and then a given readout operation is executed, whereby programs stored in these storage media can be installed on the main memory 43. In addition, by connecting given drives to the system, it is also possible to use, for example, a ROM or magnetic tape. Furthermore, it is possible to store a program in another program storage device via an information processing network, such as the Internet.

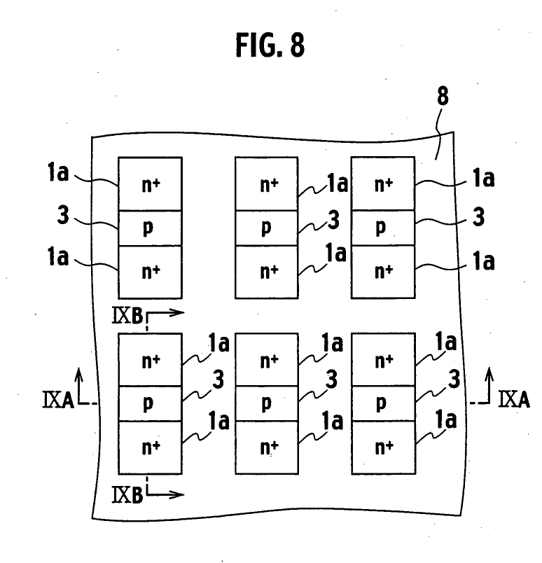

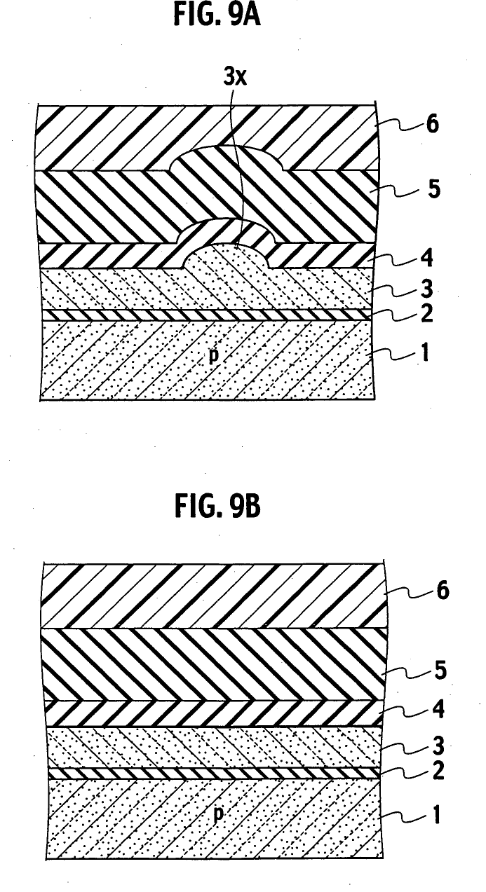

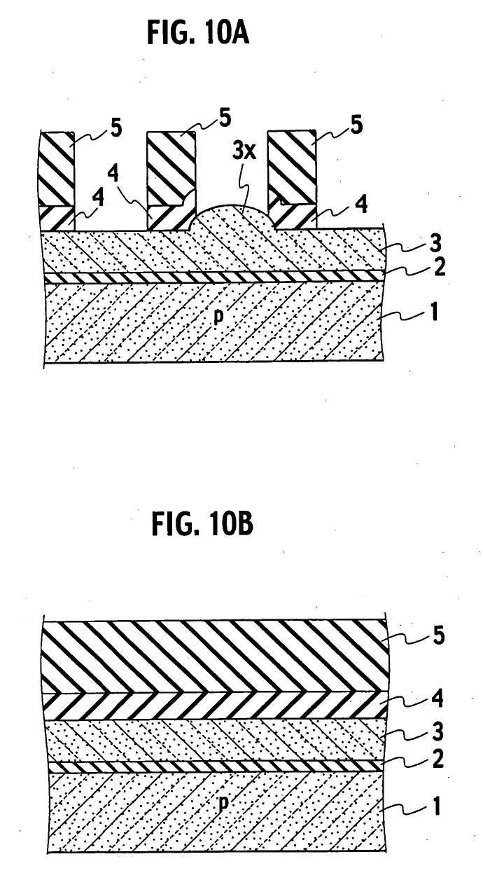

Next, an example of a method for manufacturing an electronic device (a semiconductor device) according to the embodiment of the present invention is described with reference to FIGS. 1, 2, and 9A to 15B. FIG. 8 shows a plan view of semiconductor devices formed by using the method for manufacturing a semiconductor device according to the embodiment of the present invention. FIGS. 2, 9A, 10A, . . . , 15A are process cross-sectional views taken along the line IXA-IXA in FIG. 8. FIGS. 9B, 10B, . . . , 15B are process cross-sectional views taken along the line IXB-IXB in FIG. 8. Note that, in FIG. 8, an insulating layer which covers the semiconductor layer (gate electrodes) 3, as well as gate electrodes 3, and contact plugs to impurity diffused layers 1a, and wirings connected to the contact plugs and the like are not illustrated.

A silicon semiconductor substrate 1 or the like as shown in FIG. 2 is prepared. Then, a gate insulating film 2 is deposited at a film thickness of about 1 nm on the semiconductor substrate 1 by heat oxidization or CVD. Thereafter, a semiconductor layer (gate electrodes) 3 of poly crystalline silicon or amorphous silicon is formed at a thickness of 100 nm on the gate insulating film 2. During this process, minute foreign substances may be mixed or generated in the semiconductor layer and protrusions 3x are formed on the semiconductor layer.

Next, the inspection tool 21 shown in FIG. 1 inspects the protrusions 3x on the semiconductor layer 3. A result of the inspection is stored in the inspection result memory 22. The height calculation unit 11 reads the inspection result from the inspection result memory 22 and calculates the heights “h” of the protrusions. The height “h” of the protrusions is stored in the height memory 31. The adjustment unit 12 reads the heights “h” of the protrusions from the height memory 31 and adjusts a manufacturing condition, such as an etching condition, so that the protrusions 3x are removed. The adjusted manufacturing condition is stored in the manufacturing condition memory 23.

Next, as shown in FIGS. 9A and 9B, a silicon nitride film 4 is deposited at a thickness of about 50 nm on the semiconductor layer 3 by CVD or the like. A mask film 5 of a silicon oxide film (a SiO₂ film) is deposited at a thickness of about 200 nm. A resist film. 6 is coated on the mask film 5 and the resist film 6 is delineated by lithography technology. Thereafter, by using the delineated resist film 6 as a mask, a part of the mask film 5 is selectively removed by RIE or the like as shown in FIGS. 10A and 10B. The remaining parts of the resist film 6 are removed by using resist remover or the like.

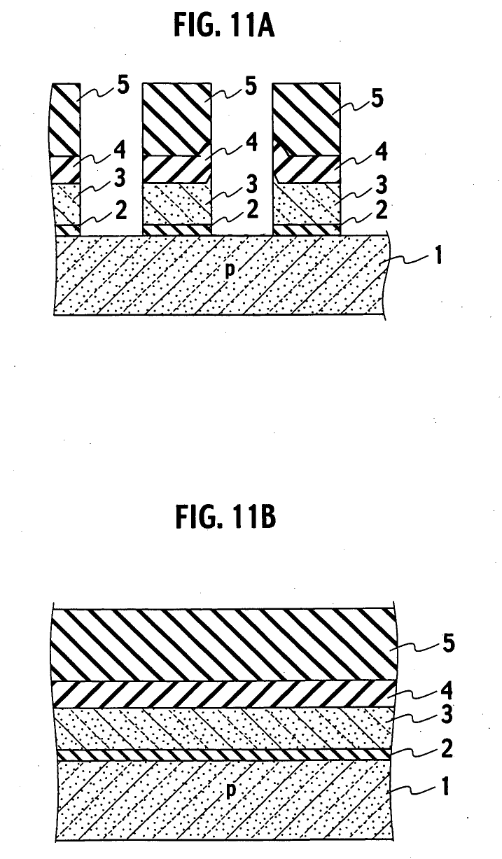

By using the mask film 5 as a mask, a part of the silicon nitride film 4 is selectively removed by RIE or the like. Selected parts of the semiconductor layer 3 and the gate insulating layer 2 are removed so that the protrusions 3x are removed as shown in FIGS. 11A and 11B. An adjusted etching time or an adjusted acceleration voltage of etching ions, stored in the manufacturing condition memory 23 shown in FIG. 1, may be used to control the amount of etching.

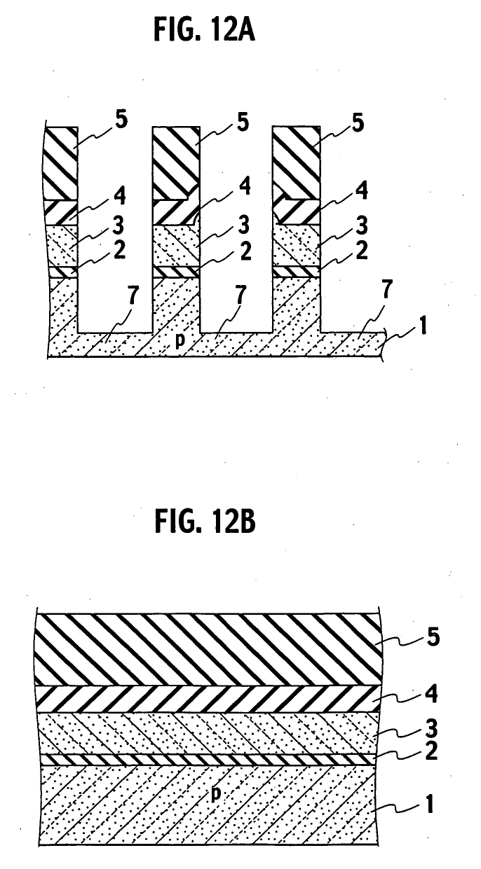

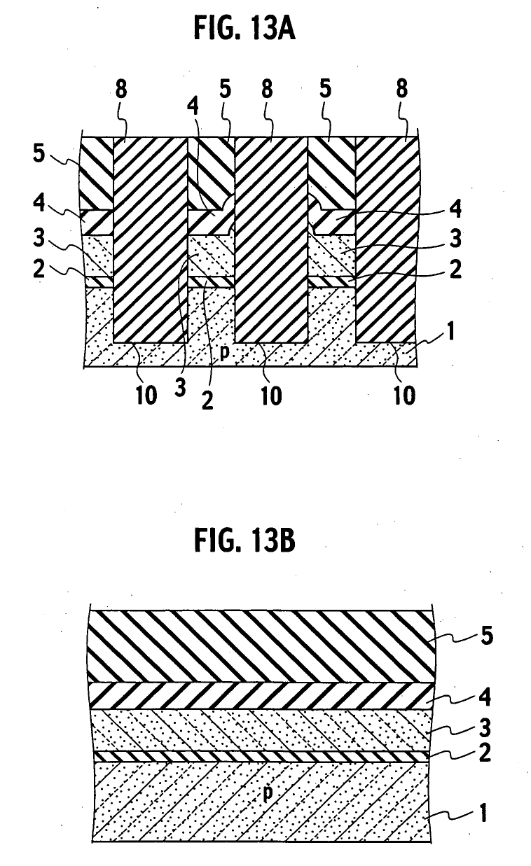

Next, a part of the semiconductor substrate 1 is removed by RIE or the like to form trenches 7 as shown in FIGS. 12A and 12B. Subsequently, the trenches 7 are filled with insulating layers by CVD or the like. Thereafter, a part of the insulating film is selectively removed by chemical mechanical polishing (CMP) or the like, forming element isolation regions 8 as shown in FIGS. 13A and 13B.

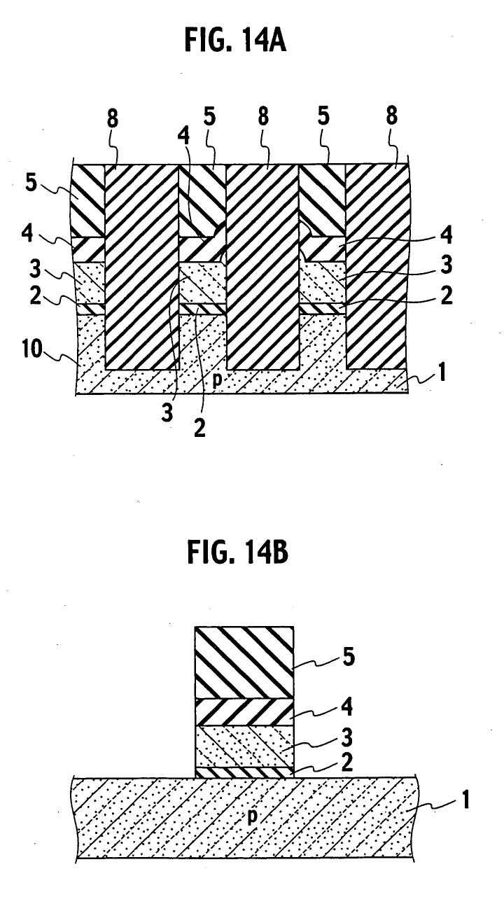

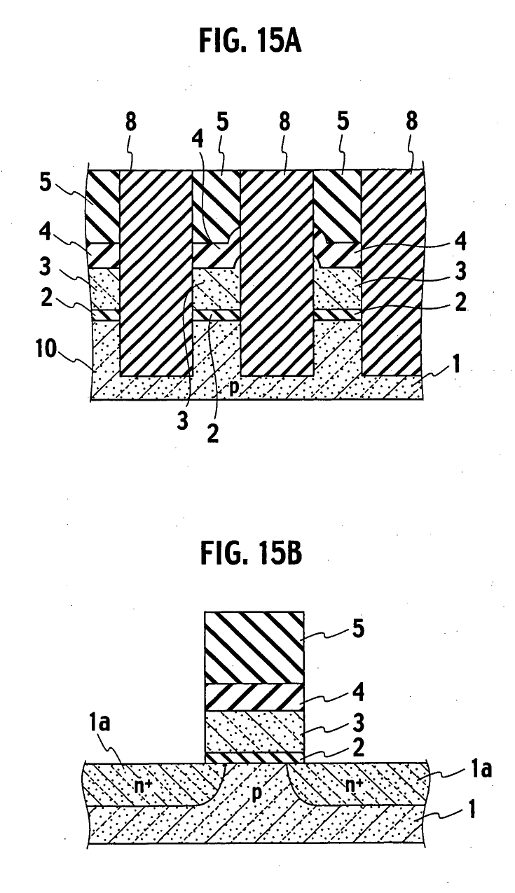

Next, selected parts of the mask film 5, the silicon nitride film 4, the semiconductor layer 3, and the gate insulating film 2 are removed by photolithography, RIE or the like as shown in FIGS. 14A and 14B. Subsequently, where the semiconductor layer 1 is a p-type, n-type impurity ions, such as phosphorus ions (P⁺) are implanted into the semiconductor substrate 1 by using the mask film 5 as a mask. Then, the implanted impurity is activated by heat treatment, thus forming n⁺ type impurity diffused layers la in self alignment on the top of the semiconductor substrate 1 as shown in FIGS. 15A and 15B. Thereafter, an insulating film is deposited and wiring is carried out, thus completing semiconductor devices.

With the method for manufacturing an electronic device (a semiconductor device) according to the embodiment of the present invention, the protrusions 3x on the semiconductor layer 3 can be removed. Therefore, processing defects caused by the protrusions 3x on the semiconductor layer 3 can be reduced, improving the yield of electronic devices.

(First Modification)

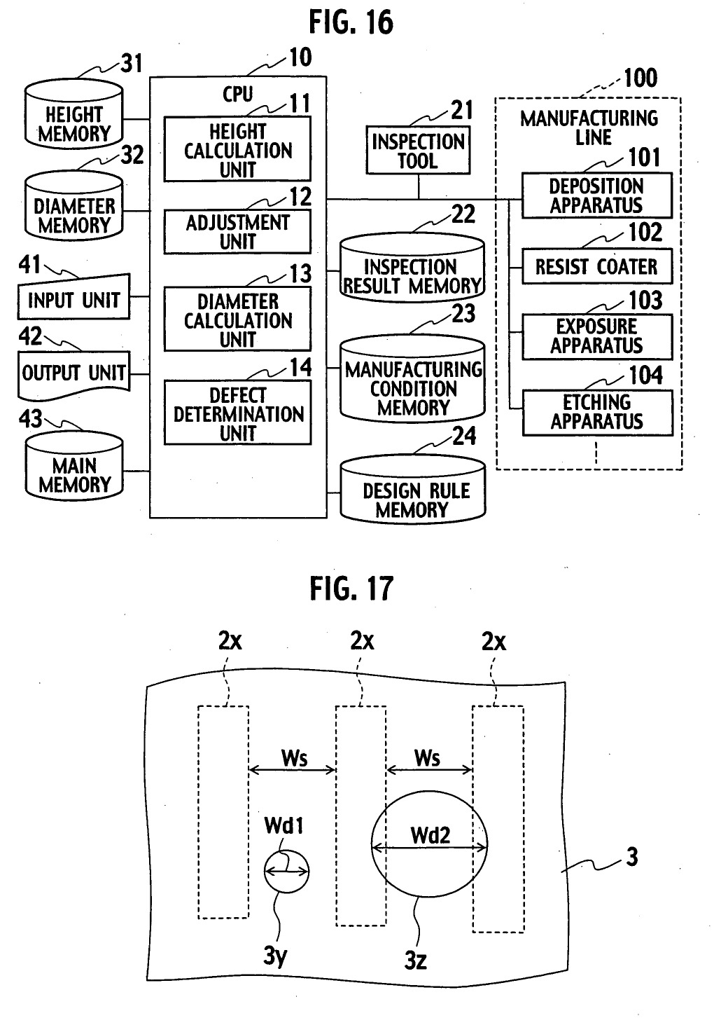

A system for adjusting a manufacturing condition according to the first modification of the embodiment of the present invention further includes a design rules memory 24 as shown in FIG. 16. The design rules memory 24 stores design rules, such as an interval Ws between gate electrodes and the like.

A CPU 10 shown in FIG. 16 is further provided with a diameter calculation unit 13 and a defect determination unit 14. The diameter calculation unit 13 extracts about 5 to 20 relatively large protrusions from a plurality of protrusions on a semiconductor layer, based on a result of an inspection carried out by an inspection tool 21. Furthermore, the diameter calculation unit 13 calculates a directed maximum diameter “Wd” of each of the extracted protrusions in a direction perpendicular to the longitudinal direction of the gate electrodes in semiconductor devices. The directed maximum diameters “Wd” are obtained as a “diameter of a protrusion.”

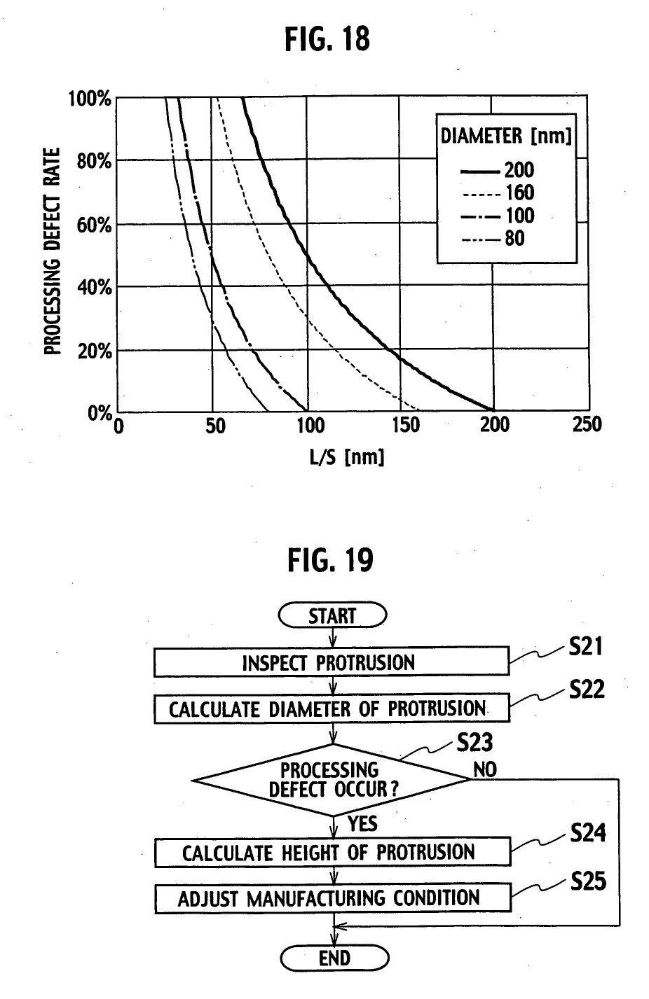

In FIG. 17, gate electrode regions 2x show positions on the semiconductor layer 3 where the gate electrodes are formed. Protrusions 3y and 3z are formed on the semiconductor layer 3. The directional maximum diameter “Wd1” of a protrusion 3y in a direction perpendicular to the longitudinal direction of the gate electrode regions 2x is smaller than the interval “Ws” between gate electrodes. On the other hand, the directed maximum diameter “Wd2” of the protrusion 3z is larger than the interval between the gate electrodes. Where the diameter of a protrusion is larger than the interval between gate electrodes, as shown in FIG. 18, it is more likely that a processing defect will occur. In other words, a processing defect is not caused by the protrusion 3y having a directed maximum diameter “Wd1” smaller than the interval “Ws” between gate electrodes. Whereas, a processing defect is likely to be caused by the protrusion 3z with a directed maximum diameter “Wd2” larger than the interval “Ws” between the gate electrodes.

The defect determination unit 14 shown in FIG. 16 determines whether or not a processing defect occurs, due to protrusions, by comparing the diameters “Wd” of the protrusions calculated by the diameter calculation unit 13 to a minimum dimension of the interval “Ws” between gate electrodes, stored in the design rules memory 24. For example, the defect determination unit 14 determines that no processing defect caused by protrusions will occur if the minimum dimension of the interval “Ws” between gate electrodes is 90 nm and the maximum diameters “Wd” of the protrusions are smaller than 90 nm.

Where the defect determination unit 14 determines that a processing defect will occur due to protrusions, the adjustment unit 12 adjusts a manufacturing condition, such as an etching condition, so that the protrusions on the semiconductor layer are removed. A diameter memory 32 stores diameters “Wd” of the protrusions calculated by the diameter calculation unit 13.

The other configurations are substantially the same as the configuration of the system for adjusting a manufacturing condition shown in FIG. 1, and a redundant description is omitted.

Next, an example of a method for adjusting a manufacturing condition according to a first modification of the embodiment of the present invention will be described, referring to the flow chart of FIG. 19. The procedure of step S21 is substantially the same as the procedure of step S11 shown in the FIG. 6, and a redundant description is omitted.

In step S22, the diameter calculation unit 13 shown in FIG. 16 reads the inspection result from the inspection result memory 22, and then calculates the diameters “Wd” of the protrusions. The diameters “Wd” of the protrusions are stored in the diameter memory 32.

In step S23, the defect determination unit 14 read the diameters “Wd” of the protrusions from the diameter memory 32. The defect determination unit 14 then determines whether a processing defect, caused by the protrusions, will occur. When it is determined that the processing defect will not occur, the processing is completed. On the other hand, when it is determined that the processing defect will occur, the procedure will advance to step S24.

The procedures of steps S24 and S25 are substantially the same as the procedures of steps S12 and S13 shown in FIG. 6, and a redundant description is omitted.

According to the first modification of the embodiment of the present invention, even when there are protrusions on a semiconductor layer, if the diameter Wd of protrusion is smaller than the interval between gate electrodes, the semiconductor device is manufactured by using predetermined manufacturing conditions. Consequently, it is not necessary to adjust manufacturing condition, and therefore it is possible to easily control the procedures.

Note that in step S23 of FIG. 19, even when determining that the processing defect does not occur, the height of protrusions may be calculated in step S24, and manufacturing conditions may be adjusted in step S25, instead of completing the processing. By controlling manufacturing conditions based on the height of the protrusions, it is possible to improve manufacturing yield.

(Second Modification)

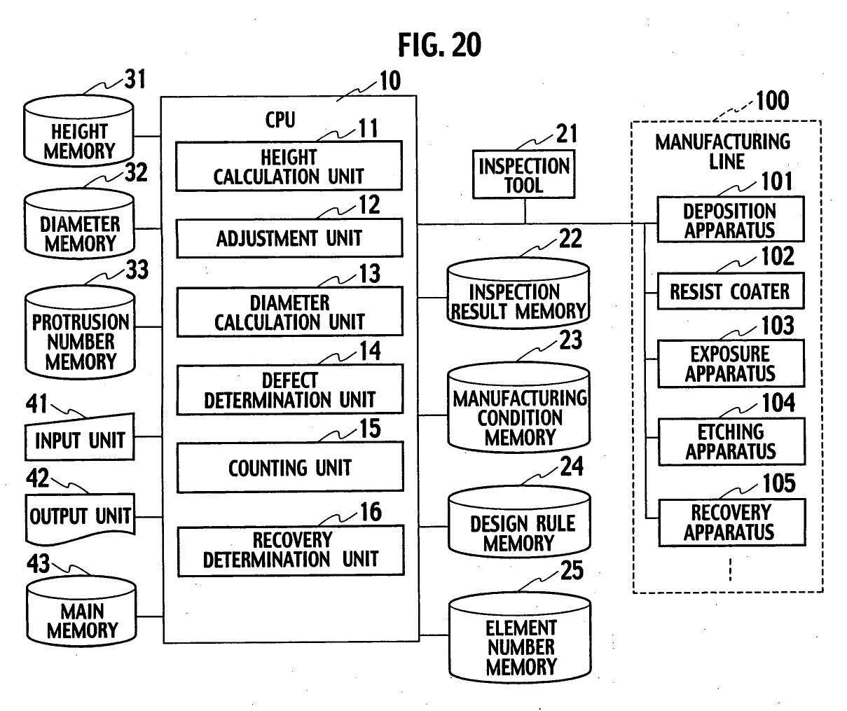

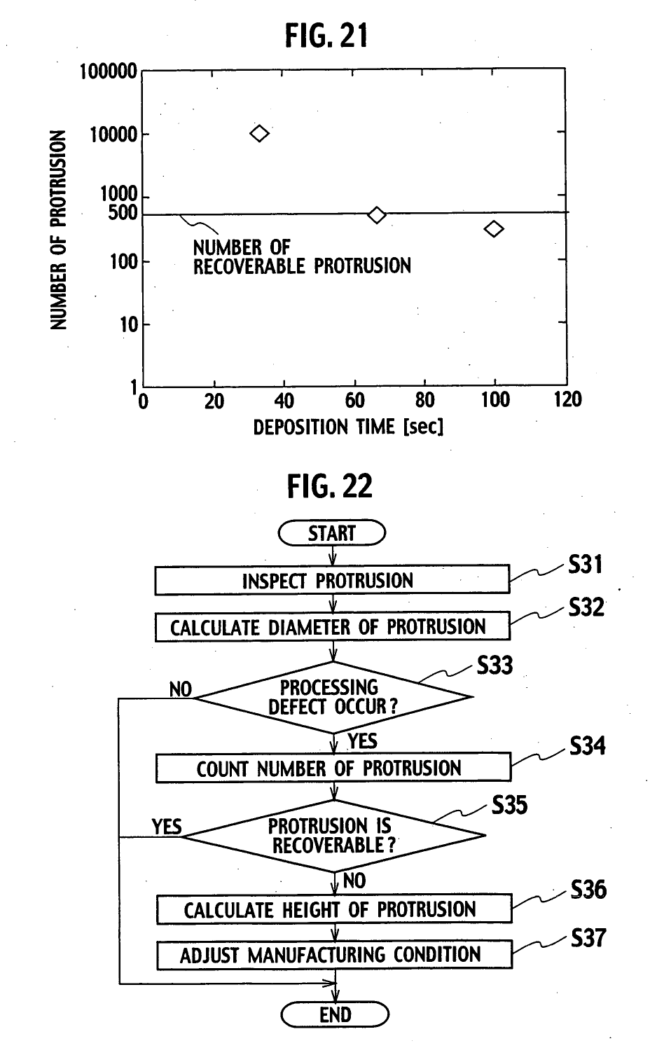

A system for adjusting a manufacturing condition according to the second modification of the embodiment of the present invention further includes an element number memory 25, as shown in FIG. 20. The element number memory 25 stores the number of recovery elements (redundant elements). The recovery elements are formed in semiconductor devices for recovering defective elements and as substitutes for the defective elements. A manufacturing condition memory 23 stores a correlation between deposition time of a semiconductor layer and the number of protrusions formed on the semiconductor layer, as shown in FIG. 21.

A CPU 10 is further provided with a counting unit 15 and a recovery determination unit 16. The counting unit 15 counts the number of protrusions based on a result of an inspection carried out by an inspection tool 21. A protrusion number memory 33 stores the number of protrusions counted by the counting unit 15.

The recovery determination unit 16 compares the number of recovery elements from the element number memory 25 to the number of protrusions counted by the counting unit 15. Where the number of recovery elements is larger than that of the protrusions, the recovery determination unit 16 determines that defects caused by the protrusions can be recovered by the recovery elements. Where the number of recovery elements is smaller than that of the protrusions, the recovery determination unit 16 determines that defects caused by the protrusions cannot be recovered. For example, where the number of recovery elements stored in the element number memory 25 is 500 and the number of protrusions counted by the counting unit 15 is 400, the recovery determination unit 16 determines that defects can be recovered.

The adjustment unit 12 adjusts a manufacturing condition when the defect determination unit 14 determines that a processing defect will occur and the recovery determination unit 16 determines that the defect cannot be recovered. For example, the adjustment unit 12 refers to the correlation between deposition time of the semiconductor layer and the number of protrusions formed on the semiconductor layer, shown in FIG. 21, from the manufacturing condition memory 23, and may adjust a deposition condition in a manufacturing process of the lots of semiconductor devices after inspection of the lots so that the number of protrusions formed on the semiconductor layer will be less than that of recovery elements. For example, the number of protrusions may be decreased by lowering deposition temperature. Note that, by bringing down deposition temperature, deposition time for obtaining a desired film thickness is also to be changed. The adjusted deposition time is also stored in the manufacturing condition memory 23.

A manufacturing line 100 shown in FIG. 20 is provided with a recovery apparatus 105, such as a laser processing system. The recovery apparatus 105 emits a laser beam to connect the recovery elements to one another instead of connecting semiconductor elements where processing defects have occurred.

The other configurations are substantially the same as the configuration of the system for adjusting a manufacturing condition shown in FIG. 1, and a redundant description is omitted.

A method for adjusting a manufacturing condition according to a second modification of the embodiment of the present invention will be described, referring to the flow chart of FIG. 22. The procedures of steps S31 and S32 are substantially the same as the procedures of steps S21 and S22 shown in FIG. 19, and a redundant description is omitted.

In step S33, when the defect determination unit 14, shown in FIG. 21, determines the occurrence of a processing defect caused by protrusions, the procedure advances to step S34. In step S34, the counting unit 15 reads a result of an inspection from the inspection result memory 22, and then calculates the number of protrusions. The number of protrusions is stored in the protrusion number memory 33. In step S35, the recovery determination unit 16 reads the number of protrusions from the protrusion number memory 33 and the number of recovery elements from element number memory 25. The recovery determination unit 16 determined whether the defect caused by protrusion is recoverable by using the recovery elements. This determination is made by comparing the number of protrusions and the number of recovery elements. Upon determining that the defects can be recovered by the recovery elements, the processing is completed. On the other hand, when it is determined that the defects are unrecoverable, the procedure advances to step S36. The procedures of steps S36 and S37 are substantially the same as the procedures of steps S12 and S13 shown in FIG. 6, and a redundant description is omitted.

According to the second modification of the embodiment of the present invention, by using predetermined manufacturing conditions when processing defects are recoverable by use of the recovery elements, it is not necessary to adjust a manufacturing condition, such as etching time, deposition condition, or the like. Therefore it is possible to improve throughput.

Note that in a method for manufacturing a semiconductor device according to a second modification of the embodiment of the present invention, the adjustment unit 12 shown in FIG. 20 may adjust deposition condition instead of etching condition, and store the adjusted deposition condition in the manufacturing condition memory 23. In this case, in a manufacturing process a lot after the semiconductor device, which is inspection object, the semiconductor layer 3 deposited on the gate insulation film 2 on the semiconductor substrate 1, as shown in FIG. 2, may be deposited so that the number of protrusions fall into the number of recovery elements, by CVD or the like, by using the adjusted deposition condition from the manufacturing condition memory 23 shown in FIG. 1.

(Third Modification)

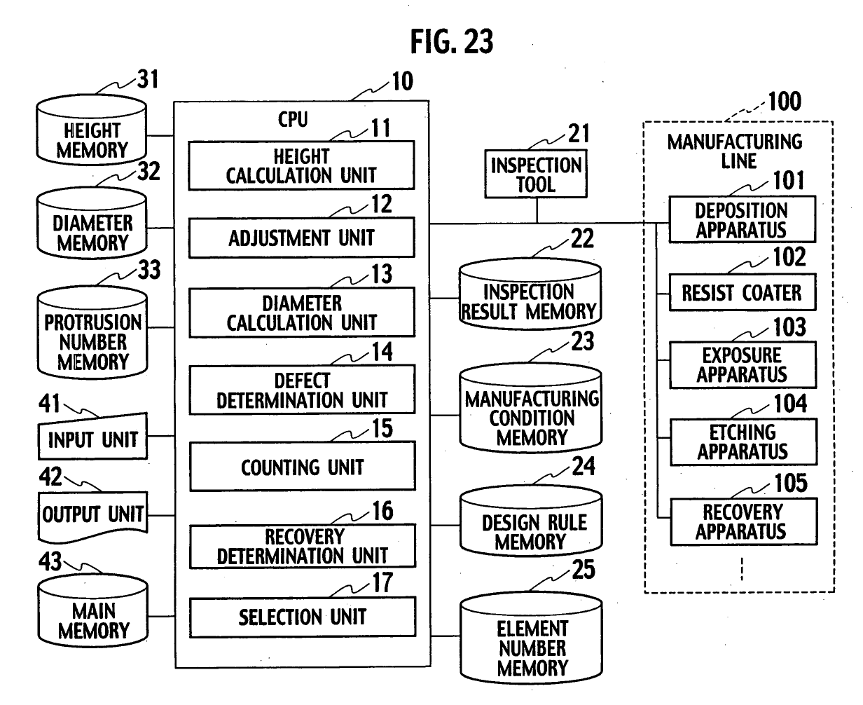

In a system for adjusting a manufacturing condition according to the third modification of the embodiment of the present invention, an adjustment unit 12 in a CPU 10 shown in FIG. 23 adjusts an etching condition by extending the etching time, based on the height “h” of protrusions on the semiconductor layer as calculated by a height calculation unit 11, so that the protrusions are removed. Further, the adjustment unit 12 adjusts a deposition condition by lowering deposition temperature and extending deposition time, based on the height “h” of protrusions calculated by the height calculation unit 11.

The CPU 10 is further provided with a selection unit 17. The selection unit 17 reads the deposition condition and etching condition adjusted by the adjustment unit 12 and selects a deposition time or an etching time. The selection is determined by which of the time is less than the other in comparison to a pre-set time, in order to remove protrusions. For example, the selection unit 17 compares an extended deposition time and an extended etching time and, if deposition time is extended more than etching time, the etching condition is selected by the selection unit 17.

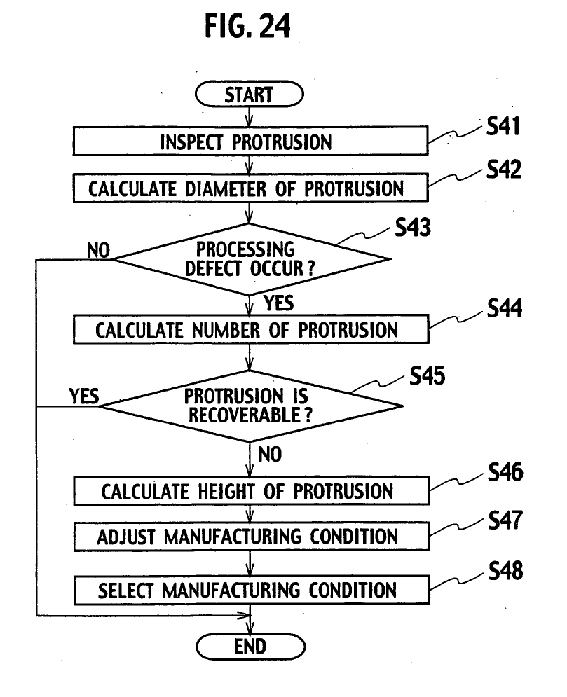

Next, a method for adjusting a manufacturing condition according to the third modification of the embodiment of the present invention will be described, referring to the flow chart of FIG. 24. The procedures of steps S41 to S46 are substantially the same as the procedures of steps S31 to S36 shown in FIG. 22, and a redundant description is omitted.

In step S47, the adjustment unit 12, shown in FIG. 23, adjusts etching condition in order to remove protrusions, by extending the etching time, based on the height “h” of the protrusions calculated by the height calculation unit 11. The adjustment unit 12 adjusts deposition condition in order to remove protrusions by decreasing the deposition temperature and by extending the deposition time, based on the height “h” of the protrusions calculated by the height calculation unit 11.

In step S48, the selection unit 17 reads the deposition condition and the etching condition adjusted by the adjustment unit 12, and then selects one of the deposition condition and the etching condition which has a less extended time than the other. The selected manufacturing condition is stored in the manufacturing condition memory 23.

According to the third modification of the embodiment of the present invention, the selection unit 17 selects one of the etching condition and the deposition condition, which requires less time than the other, so as to improve throughput. Therefore by using selected manufacturing conditions, it is possible to increase throughput by adjusting a specific manufacturing conditions.

Various modifications will become possible for those skilled in the art after receiving the teachings of the present disclosure without departing from the scope thereof.

For example, in the flowchart shown in FIG. 24, calculation of diameters “Wd” of protrusions in step S42, counting the number of protrusions in step 44, and calculation of heights “h” of protrusions in step S46 may be carried out after an inspection in step S41, and thereafter, determination of whether a processing defect will occur in step S43 and determination of whether the defect can be recovered in step S45 may be carried out.

Furthermore, instead of adjusting one of etching time and acceleration voltage, the adjustment unit 12, shown in FIG. 1, may adjust both etching time and acceleration voltage of etching ions so that the same amount of etching is achieved.

Further, the foregoing embodiment describes an example of a method for manufacturing a semiconductor device. It should be easily understood from the above descriptions that the present invention can also be applied to a method for manufacturing electronic devices including a liquid crystal device, a magnetic storage medium, an optical storage medium, a thin-film magnetic head, a superconductive element, and the like. Moreover, protrusions to be inspected may be any type of protrusion on an insulating layer such as an oxide film and a substance layer such as a metal layer, in addition to the protrusion 3x on the semiconductor layer 3 shown in FIG. 2.

What is claimed is:

1. A system for adjusting a manufacturing condition of an electronic device comprising:
an inspection tool configured to inspect a plurality of protrusions on a substance layer for manufacturing an electronic device;
a height calculation unit configured to calculate each of heights of the protrusions, based on the inspection result; and
an adjustment unit configured to adjust a manufacturing condition of the electronic device in order to remove the protrusions, based on the heights.

2. The system of claim 1, wherein the height calculation unit extracts a relatively large protrusion from among the protrusions on the substance layer, and calculates the height of the extracted protrusion.

3. The system of claim 1, wherein the adjustment unit adjusts an etching condition for etching the substance layer, the etching condition is assigned as the manufacturing condition and adjusted to etch away the protrusions.

4. The system of claim 3, further comprising an etching apparatus configured to etch the substance layer by using the adjusted etching condition.

5. The system of claim 4, wherein the adjustment unit adjusts at least one of etching time and acceleration voltage of etching ions, for etching the substance layer in order to remove the protrusion.

6. The system of claim 1, wherein the adjustment unit adjusts a deposition condition for depositing the substance layer, the deposition condition is assigned as the manufacturing condition.

7. The system of claim 6, further comprising a deposition apparatus configured to deposit the substance layer, by use of the adjusted deposition condition.

8. The system of claim 1, further comprising a selection unit selecting one of an etching condition for etching the substance layer and a deposition condition for depositing the substance layer, as the manufacturing condition.

9. The system of claim 8, wherein the selection unit selects one of the deposition time and the etching time that is less than the other, as compared to a pre-set time.

10. The system of claim 1, further comprising:
a diameter calculation unit configured to calculate diameters of the protrusions; and
a defect determination unit configured to determinate whether a processing defect will occur caused by the protrusions, based on the diameters.

11. The system of claim 1, further comprising:
a counting unit configured to count a number of protrusions; and
a recovery determination unit configured to determinate whether a defect caused by the protrusions is recoverable by using a recovery elements, based on the number of protrusions.

12. A method for adjusting a manufacturing condition of an electronic device comprising:
inspecting a plurality of protrusions on a substance layer for manufacturing an electronic device;
calculating each of heights of the protrusions, based on the inspection result; and
adjusting a manufacturing condition of the electronic device, in order to remove the protrusions, based on the heights.

13. The method of claim 12, wherein calculating the height comprises:
extracting a relatively large protrusion from among the protrusions on the substance layer; and
calculating the height of the extracted protrusion.

14. The method of claim 12, wherein adjusting the manufacturing condition comprises:
adjusting an etching condition for etching the substance layer, the etching condition is assigned as the manufacturing condition and adjusted to etch away the protrusions.

15. The method of claim 14, wherein adjusting the etching condition comprises:
adjusting at least one of etching time for etching the substance layer and acceleration voltage of etching ions.

16. The method of claim 12, wherein adjusting the manufacturing condition comprises:
adjusting a deposition condition for depositing the substance layer, the deposition condition is assigned as the manufacturing condition.

17. The method of claim 12, wherein adjusting the manufacturing condition comprises:
adjusting one of an etching condition for etching the substance layer, and a deposition condition for depositing the substance layer.

18. The method of claim 12, further comprising:
calculating each of diameters of the protrusions; and
determinating whether a processing defect will occur caused by the protrusions, based on the diameters.

19. The method of claim 12, further comprising:
calculating a number of protrusions; and
determinating whether a defect caused by the protrusions is recoverable by use of recovery elements, based on the number of protrusions.

20. A method for manufacturing an electronic device comprising:
depositing a substance layer on a substrate;
inspecting a plurality of protrusions on the substance layer;
calculating each of heights of the protrusions, based on the inspection result;
adjusting a condition for processing the substance layer, based on the heights; and
processing the substance layer so as to manufacture the electronic device, by using the adjusted condition in order to remove the protrusions.
